(19) United States
(12) Patent Application Publication
(10) Pub. No.: US 2007/0035213 A1
(43) Pub. Date: Feb. 15, 2007

(54) PIEZOELECTRIC PUMP

(75) Inventor: Jiro Nakajima, Niigata-ken (JP)

Correspondence Address: BRINKS HOFER GILSON & LIONE, P.O. BOX 10395, CHICAGO, IL, 60610, US

(73) Assignee: ALPS ELECTRIC CO., LTD., Tokyo (JP)

(21) Appl. No.: 11/460,478

(22) Filed: Jul. 27, 2006

(30) Foreign Application Priority Data
Aug. 10, 2005 (JP) 2005-232354

(51) Int. Cl. H01L 41/053

(52) U.S. Cl. 310/348

(57) ABSTRACT

A piezoelectric pump is provided. The piezoelectric pump includes a piezoelectric vibrator including a piezoelectric member. Recesses of a housing form variable volume chambers between the recesses and the piezoelectric vibrator. Sealing members are provided along the recesses and in contact with the piezoelectric vibrator to form the variable volume chambers. A feeding terminal for the piezoelectric member is provided on the at least one of the front surface and the rear surface of the piezoelectric vibrator. The planar shape of each of the piezoelectric vibrator and the variable volume chambers and the position of the feeding terminal are set such that the sealing members do not intersect with the feeding terminal in a single plane.

This application claims the benefit of the Japanese Patent Application No. 2005-232354 filed on Aug. 10, 2005, which is hereby incorporated by reference.

### BACKGROUND

### Field

a piezoelectric pump and a wiring structure for a piezoelectric vibrator is provided. Related Art

A piezoelectric pump obtains a pumping action by causing a plate-like piezoelectric vibrator to vibrate. The piezoelectric vibrator is superimposed on a recess formed in a housing. A sealing member is provided along the recess to contact the piezoelectric vibrator forms a variable volume chamber. The variable volume chamber is connected to a pair of flow passages that are provided with a pair of non-return valves of different flow directions (i.e., a non-return valve for allowing a fluid to flow into the variable volume chamber and a non-return valve for allowing a fluid to flow from the variable volume chamber).

When the piezoelectric vibrator is vibrated, the volume of the variable volume chamber changes. An operation is repeated in which one of the pair of the non-return valves is closed and the other one of the pair of the non-return valves is opened. Thereby, the pumping action is obtained. The piezoelectric pump can be formed into a thin shape and thus is used also as a cooling water circulating pump for a water-cooled notebook computer or a desktop computer, for example.

The piezoelectric vibrator is formed by layering a piezoelectric member on at least one of the front surface and the rear surface of a shim (i.e., a thin conductive metal plate). The piezoelectric member is provided with a polarization characteristic in a direction of the front surface and the rear surface thereof. When positive and negative polarities are applied to a region between the front surface and the rear surface in a direction the same as or opposite to the polarization direction, the surface area of one of the front surface and the rear surface is increased, and the surface area of the other one of the front surface and the rear surface is decreased.

Due to this characteristic of the piezoelectric member, when the positive and negative polarities applied to the front surface and the rear surface of the piezoelectric member are alternated, a cycle is repeated in which one of the front surface and the rear surface is expanded and the other one of the front surface and the rear surface is contracted. Thereby, the shim is caused to vibrate.

The above-described piezoelectric vibrator is divided into two known types, for example, a unimorph type in which the piezoelectric member is provided on only one of the front surface and the rear surface of the shim, and a bimorph type in which the piezoelectric member is provided on each of the front surface and the rear surface of the shim. Conventional piezoelectric pumps are described in Japanese Unexamined Patent Application Publication No. 61-28776 and Japanese Unexamined Utility Model Registration Application Publication Nos. 5-14574 and 4-137284, for example.

Conventionally, in the piezoelectric pump described above, the planar shape of the piezoelectric vibrator (i.e., the piezoelectric member forming the piezoelectric vibrator) and the planar shape of the variable volume chamber (i.e., the planar shape of each of the recess of the housing and the sealing member provided along the recess) are both circular. That is, the sealing member is an O-shaped ring. In fact, the theoretical pumping efficiency is highest when the planar shape of each of the piezoelectric vibrator and the variable volume chamber is circular.

The piezoelectric pump in which the piezoelectric vibrator and the variable volume chamber each have the circular planer shape. A wiring needs to be provided to the piezoelectric member which forms the surface of the piezoelectric vibrator. In the conventional structure, a feeding terminal for the piezoelectric member inevitably intersects with the O-shaped ring in a single plane. The feeding terminal is formed as thin as possible. When the feeding terminal intersects with the O-shaped ring, however, a part of the O-shaped ring intersecting with the feeding terminal is deformed more excessively than the other part of the O-shaped ring, although the degree of the deformation is slight.

When a commercial power supply is used, the piezoelectric vibrator is vibrated at 50 Hz or 60 Hz. Therefore, even such slight but excessive deformation of the O-shaped ring becomes a factor for deteriorating the durability of the O-shaped ring and thus decreasing the lifetime of the piezoelectric pump.

### SUMMARY

The present invention has been made on the basis of a conclusion that the deterioration in durability of the sealing member is caused by the intersection of the sealing members and the feeding terminal in a single plane, and that the durability of the sealing member can be improved by eliminating the intersectional relationship even at the cost of some degree of the pumping efficiency. It has been confirmed that, even if the intersectional relationship is eliminated, the decrease in the pumping efficiency is slight and thus has little practical effect.

According to one embodiment, a piezoelectric pump includes recesses formed in a housing. A piezoelectric vibrator is superimposed between the recesses. Sealing members are provided along the recesses and in contact with the piezoelectric vibrator to form variable volume chambers. In the piezoelectric pump, each of the variable volume chambers is smaller in a planar shape than a piezoelectric member provided on a surface of the piezoelectric vibrator. A wiring is provided to the piezoelectric member at the outer side of the planar shape of the variable volume chamber. The degree by which “the variable volume chamber is smaller in the planar shape than the piezoelectric member” is the degree ensuring a wiring area at the outer side of the variable volume chamber.

The piezoelectric member provided on the surface of the piezoelectric vibrator may have a circular planar shape, which is a common shape, and the variable volume chamber may have a noncircular planar shape in which a part of a circle is made noncircular.

Each of the sealing members which define the variable volume chambers may be formed into a deformed D-shape including a large arc portion which is a part of a circle larger than a semicircle thereof, and a straight-line portion which is a straight line connecting opposite ends of the large arc portion. The deformed D-shape may be modified into a deformed circular-shape including a supplemental arc portion which is connected to the large arc portion at the outer side of the straight-line portion to form a circle together with the large arc portion. In this embodiment, the supplemental arc portion does not have a function of the sealing member. That is, this embodiment is designed in consideration of convenience in molding the seal member.

The sealing member may be formed into another shape, for example, a deformed horseshoe-shape including a large arc portion which is a part of a circle larger than a semicircle thereof, and an arc portion which connects opposite ends of the large arc portion.

The piezoelectric vibrator may be either one of a unimorph-type piezoelectric vibrator that includes a shim located at the center thereof and the piezoelectric member provided on one of the front surface and the rear surface of the shim, and a bimorph-type piezoelectric vibrator that includes a shim located at the center thereof and the piezoelectric member provided on each of the front surface and the rear surface of the shim. Preferably, the piezoelectric vibrator may be the bimorph-type, since the vibration amplitude of the piezoelectric vibrator can be increased.

A piezoelectric pump includes a piezoelectric vibrator including a piezoelectric member on at least one of the front surface and the rear surface thereof. Recesses of a housing form variable volume chambers between the recesses and the piezoelectric vibrator. Sealing members provided along the recesses and in contact with the piezoelectric vibrator to form the variable volume chambers. A feeding terminal for the piezoelectric member provided on the at least one of the front surface and the rear surface of the piezoelectric vibrator. In the piezoelectric pump, the planar shape of each of the piezoelectric vibrator and the variable volume chambers and the position of the feeding terminal are set such that the sealing members and the feeding terminal do not intersect with each other in a single plane.

According to the above embodiment, a long-life piezoelectric pump having sealing members with improved durability can be obtained.

### BRIEF DESCRIPTION OF THE DRAWINGS

FIG. 1 is a vertical cross-sectional view that illustrates the principle of a piezoelectric pump using a piezoelectric vibrator;

FIG. 2 is an exploded perspective view schematically that illustrates a specific configuration example of a bimorph-type piezoelectric vibrator;

FIG. 3 is an exploded perspective view that illustrates an embodiment of a piezoelectric pump;

FIG. 4 is a perspective view of relevant parts of the embodiment of the piezoelectric pump;

FIG. 5 is a partial plan view of the piezoelectric pump illustrated in FIGS. 3 and 4;

FIG. 6 is a cross-sectional view of the piezoelectric pump illustrated in FIG. 5, as cut along the VI-VI line; and

FIGS. 7A and 7B are plan views that illustrates other examples of the shape of the sealing member (i.e., the variable volume chamber) used in the piezoelectric pump.

### DESCRIPTION

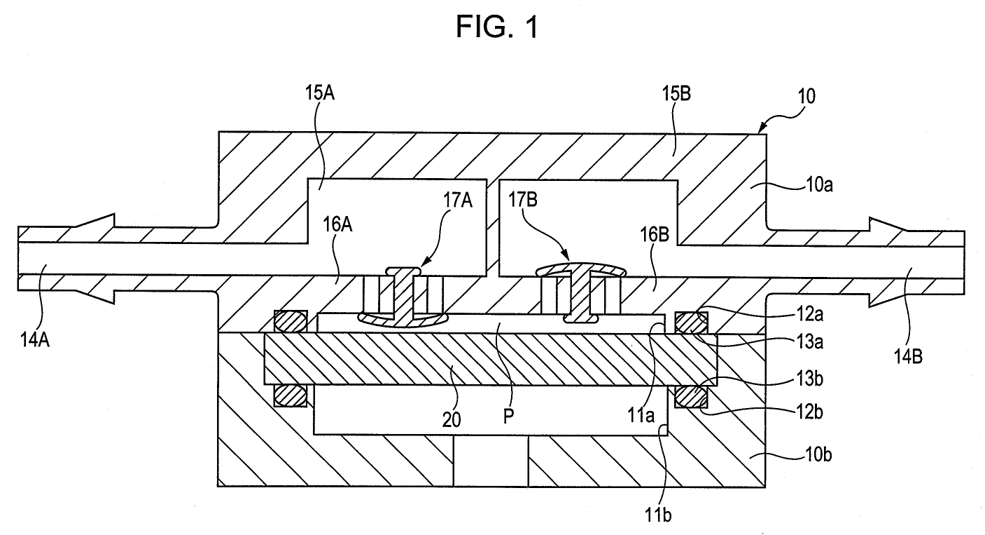

FIG. 1 is a diagram that illustrates the principle of a piezoelectric pump that includes a piezoelectric vibrator. A housing 10 is formed by an upper housing 10a and a lower housing 10b. A surface of the upper housing 10a facing the lower housing 10b is provided with a recess 11a and a sealing ring groove 12a formed along the recess 11a, while a surface of the lower housing 10b facing the upper housing 10a is provided with a recess 11b and a sealing ring groove 12b formed along the recess 11b. In a space between the upper housing 10a and the lower housing 10b, a piezoelectric vibrator 20 is attached in a sandwiched manner such that the front surface and the rear surface of the piezoelectric vibrator 20 are in contact with sealing rings 13a and 13b that are inserted in the corresponding sealing ring grooves 12a and 12b. A variable volume chamber P is formed between the sealing ring 13a and the piezoelectric vibrator 20.

Another variable volume chamber is formed between the sealing ring 13b and the piezoelectric vibrator 20. The another variable volume chamber, however, does not have a pumping action. The thickness of the piezoelectric vibrator 20 is illustrated in an exaggerated manner, and the actual thickness of the piezoelectric vibrator 20 is smaller than about 1.5 mm. The recesses 11a and 11b are each formed into a shallow shape so that the piezoelectric vibrator 20 extends along the recesses 11a and 11b.

The upper housing 10a is formed with an entrance port 14A and an exit port 14B that allows passage of cooling water (i.e., a liquid). The entrance port 14A communicates with an entrance-side liquid storing chamber 15A, while the exit port 14B communicates with an exit-side liquid storing chamber 15B. Dividing walls 16A and 16B are located between the entrance-side liquid storing chamber 15A and the variable volume chamber P and between the exit-side liquid storing chamber 15B and the variable volume chamber P.

The dividing walls 16A and 16B are provided with umbrellas (i.e., non-return valves) 17A and 17B. The umbrella 17A is a non-return valve that allows a fluid to flow from the entrance port 14A (the entrance-side liquid storing chamber 15A) into the variable volume chamber P but does not allow a fluid to flow in an inverse direction. The umbrella 17B is a non-return valve which allows a fluid to flow from the variable volume chamber P into the exit port 14B (the exit-side liquid storing chamber 15B) but does not allow a fluid to flow in an inverse direction.

In the thus configured piezoelectric pump, the piezoelectric vibrator 20 is resiliently deformed in forward and reverse directions. In a process in which the volume of the variable volume chamber P is increased, the umbrella 17A is opened and the umbrella 17B is closed, and the liquid flows from the cooling water entrance port 14A (the entrance-side liquid storing chamber 15A) into the variable volume chamber P. In a process in which the volume of the variable volume chamber P is decreased, the umbrella 17B is opened and the umbrella 17A is closed, and the liquid flows from the variable volume chamber P into the exit port 14B (the exit-side liquid storing chamber 15B). Therefore, as the piezoelectric vibrator 20 continues to be resiliently deformed (i.e., vibrated) in the forward and reverse directions, a pumping action can be obtained.

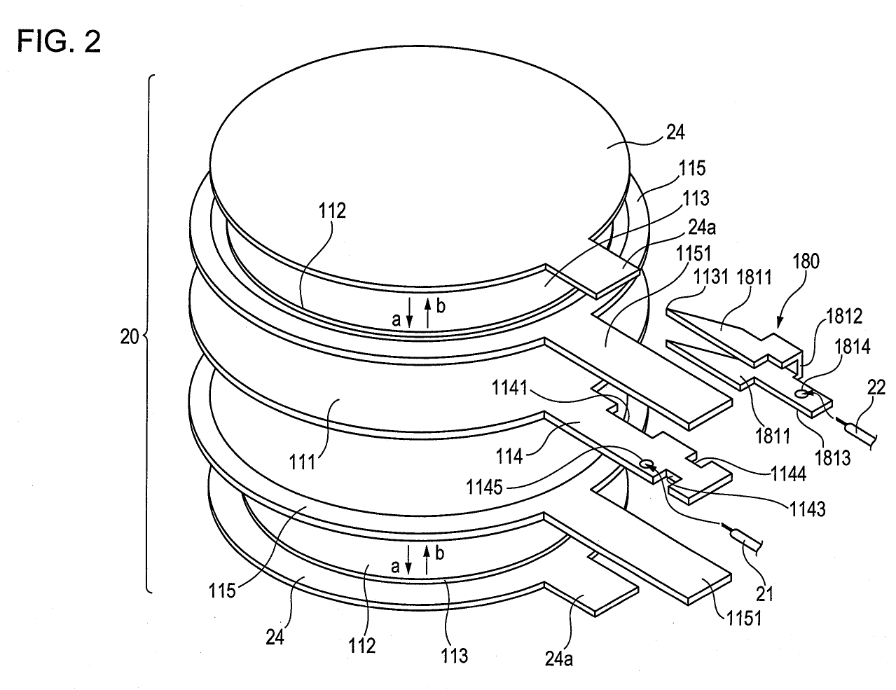

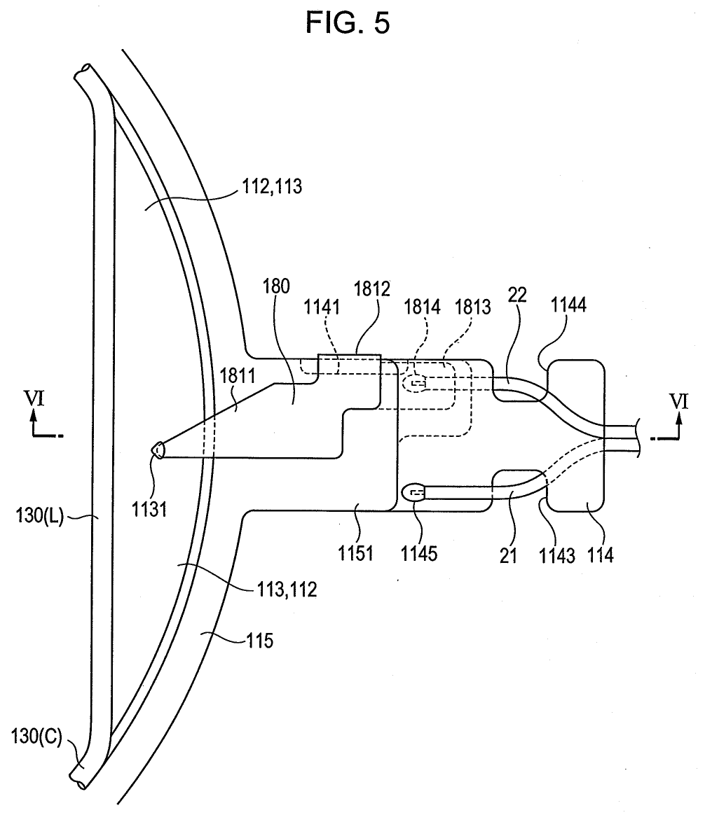

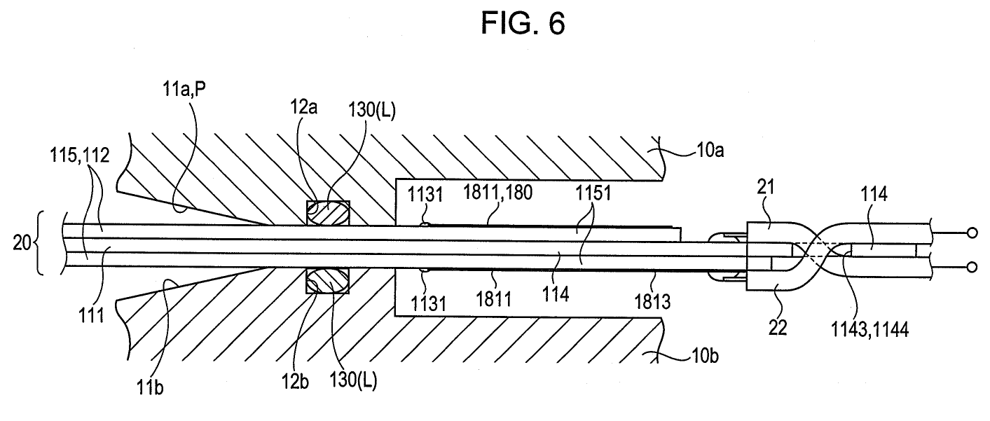

The piezoelectric vibrator 20 can be either one of a unimorph type and a bimorph type. A pattern diagram that illustrates an embodiment of the bimorph-type piezoelectric vibrator proposed by the present applicant in Japanese Patent Application No. 2004-192483 is shown in FIG. 2 (and in FIGS. 5 and 6). The bimorph-type piezoelectric vibrator includes a circular shim 111 at the center thereof, and a piezoelectric member 112 layered on each of the front surface and the rear surface of the shim 111. The shim 111 is formed by a thin conductive metal plate material, such as a 42 alloy plate which has a thickness of approximately 0.2 mm, and 42% of which is Ni and the balance is Fe, for example. The piezoelectric member 112 is formed of PZT (Pb (Zr, Ti) O₃) having a thickness of approximately 0.3 mm, for example, and has been subjected to a polarization treatment in a direction of the front surface and the rear surface of the piezoelectric member 112. The polarization treatment is performed in the same direction on the pair of the piezoelectric members 112 located on the front surface and the rear surface of the shim 111. As shown inn FIG. 2, the polarization direction of the pair of the piezoelectric members 112 is indicated by an arrow a or b, the polarization treatment is performed in the same direction with respect to the thickness direction of the shim 111. Polarization characteristics of surfaces of the pair of the piezoelectric members 112 in contact with the front surface and the rear surface of the shim 111 are different from each other, and polarization characteristics of exposed surfaces of the pair of the piezoelectric members 112 are different from each other. In this manner, if the polarization treatment is performed in the same direction on the pair of the piezoelectric members 112 in contact with the front surface and the rear surface of the shim 111, the amount of displacement of the shim 111 can be increased by alternately applying positive and negative voltages between the shim 111 and the exposed surfaces of the pair of the piezoelectric members 112 in contact with the front surface and the rear surface of the shim 111.

The surfaces of the pair of the piezoelectric members 112 facing the shim 111 are adhered to the shim 111 to be entirely in conduction with the shim 111, while the exposed surfaces of the pair of the piezoelectric members 112 not facing the shim 111 are entirely formed with respective film electrodes 113. Each of the film electrodes 113 is formed by, for example, screen-printing a conductive paste (a gold paste or a solver paste) and having the paste subjected to firing.

A feeding terminal 180 includes a pair of contacts 1811, a connection piece 1812, and a wiring connection portion 1813. The pair of contacts 1811 and the connection piece 1812 form a C-shaped cross section. The contacts 1811 forming the pair are the same in shape, and each of the contacts 1811 has an approximately triangular planar shape, which is wide at a side of the wiring connection portion 1813 located at an outer side of the piezoelectric vibrator 20 and which gradually becomes narrower in width toward the center of the piezoelectric vibrator 20. The contact 1811 is narrowest in width at a soldered portion 1131 where the contact 1811 is soldered with the corresponding film electrode 113 of the piezoelectric vibrator 20, and becomes wider in width toward the outside of the piezoelectric vibrator 20.

A wiring connection projection 114, which is formed to the shim 111 of the piezoelectric vibrator 20 and projects in a radial direction of the shim 111, extends between the pair of the contacts 1811. The wiring connection projection 114 is formed with an insulating recess 1141 for ensuring an open space between the wiring connection projection 114 and the connection piece 1812 that connects the pair of the contacts 1811.

Toric insulating spacer rings 115 are located on and under the shim 111. From each of the pair of the insulating spacer rings 115 provided on and under the shim 111, a strip-shaped insulating plate 1151 extends between a corresponding one of the pair of the contacts 1811 and the wiring connection projection 114 that prevent a short circuit from occurring between the shim 111 and the feeding terminal 180. The strip-shaped insulating plate 1151 further prevents the connection piece 1812 of the feeding terminal 180 from moving toward the insulating recess 1141 of the shim 111. Accordingly, insulation is securely performed.

The wiring connection projection 114 of the shim 111 is also formed with a pair of lead wire retaining recesses 1143 and 1144, which are located symmetrically at opposite sides in the width direction of the wiring connection projection 114 at positions more outward from the piezoelectric vibrator 20 than the insulating recess 1141 is. At a position inward from one of the lead wire retaining recesses 1143, a soldering through hole 1145 is formed.

Meanwhile, the wiring connection portion 1813 of the feeding terminal 180 is formed with a soldering through hole 1814 to correspond to the soldering through hole 1145 of the wiring connection projection 114. The soldering through holes 1145 and 1814 are different in planar position and are soldered with lead wires 21 and 22. If the soldering strength of the soldering through holes 1145 and 1814 is increased, and if the planar positions of the soldering through holes 1145 and 1814 are displaced to be different from each other, the thickness of the piezoelectric vibrator 20 as a whole can be reduced. Further, with the lead wires 21 and 22 hooked and retained by the lead wire retaining recesses 1143 and 1144. Resistance of the lead wires 21 and 22 from being released is increased.

The surfaces of the piezoelectric vibrator 20 are adhered to PPS films (i.e., insulating films) 24 (refer to FIG. 2). Each of the PPS films 24 includes a radial tongue portion 24a which extends on the feeding terminal 180. Thereby, the contacts 1811 and the film electrodes 113 of the piezoelectric vibrator 20 are prevented from being separated.

According to the above-described wiring structure of and around the wiring connection projection 114 of the shim 111 and the feeding terminal 180, a wiring can be securely provided to the shim 111 and the film electrodes 113 without preventing the movement of the piezoelectric vibrator 20.

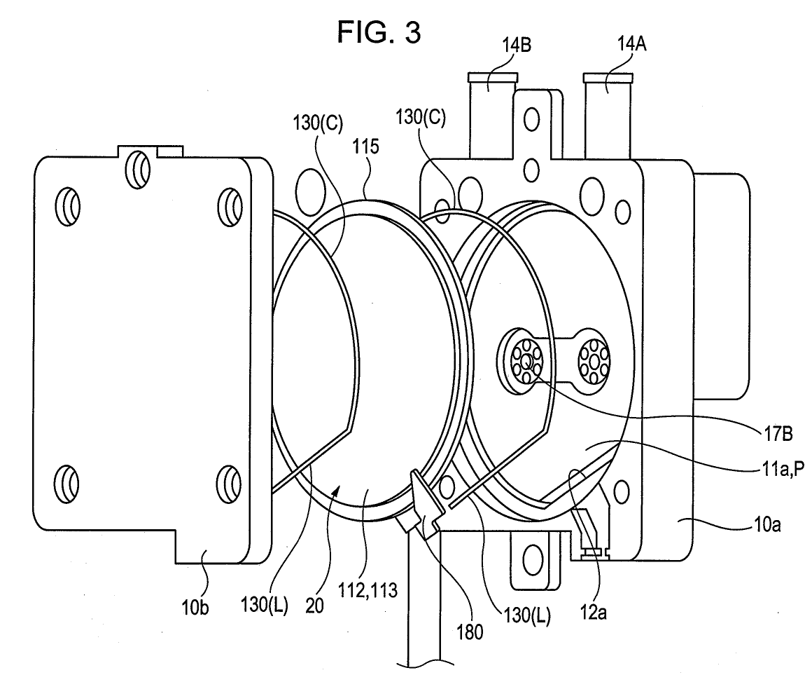

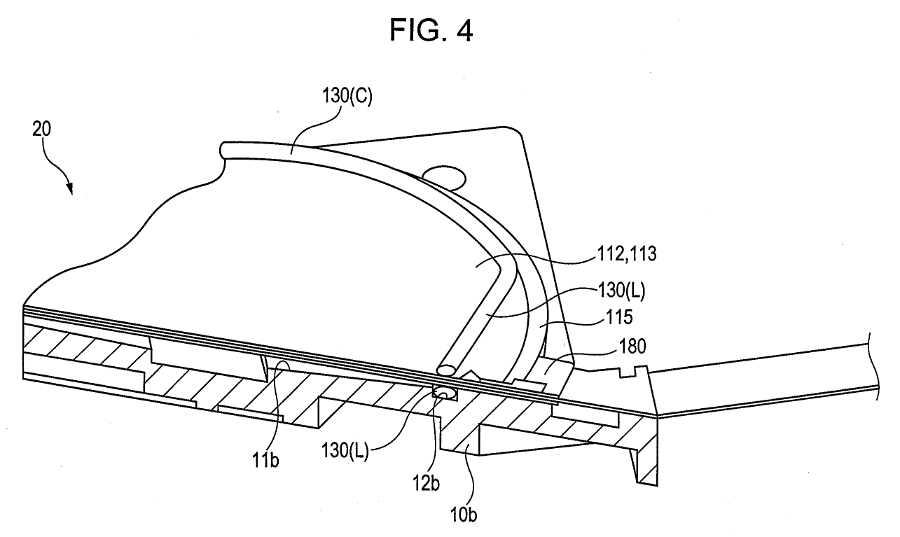

As illustrated in FIGS. 3 to 6, the shape of each of the variable volume chambers (which are defined by the recesses 11a and 11b of the housing 10 and the sealing members 130) is formed into a noncircular shape (i.e., a shape corresponding to an arc portion cut from the piezoelectric vibrator 20) to be smaller than the piezoelectric vibrator 20, the basic form of which is a circular plane as described above.

In FIGS. 3 to 6, the sealing rings 13a and 13b are the same in shape and thus are designated by a single reference numeral 130. At the outer side of the variable volume chambers, the wiring is provided to the piezoelectric members 112 (i.e., the film electrodes 113) of the piezoelectric vibrator 20 via the feeding terminal 180. The feeding terminal 180 for the piezoelectric members 112 of the piezoelectric vibrator 20 does not intersect with the sealing members 130. Therefore, the sealing members 130 are not locally deformed, and the durability of the sealing members 130 can be improved.

In FIGS. 3 to 6, each of the sealing members 130 defining the variable volume chambers is formed into a deformed D-shape including a large arc portion 130(C) which is a part of a circle larger than a semicircle thereof, and a straight-line portion 130(L) which is a straight line connecting opposite ends of the large arc portion 130(C). The position of the straight-line portion 130(L) is set to be outward as much as possible so as to make the large arc portion 130(C) as large as possible, so far as a wiring area for the piezoelectric members 112 can be saved at the outer side of the straight-line portion 130(L). With the position of the straight-line portion 130(L) thus set to be outward as much as possible, the decrease in the pumping efficiency can be minimized.

In another perspective, the position of the straight-line portion 130(L) is set to prevent the straight-line portion 130(L) from having a permanent set due to reciprocating vibration of the piezoelectric vibrator 20. That is, in the above-described circular bimorph-type piezoelectric vibrator 20, the shim 111 forms one common electrode, and the exposed surfaces of the pair of the piezoelectric members 112 (i.e., the film electrodes 113) form the other common electrode. In this piezoelectric vibrator 20, when an alternating electric field is caused to generate, an operation is repeated in which either one of the front surface and the rear surface of the piezoelectric vibrator 20 is expanded and the other one of the front surface and the rear surface of the piezoelectric vibrator 20 is contracted. The vibration amplitude of the piezoelectric vibrator 20 becomes the greatest at the center thereof and decreases toward the periphery thereof. Therefore, the position of the straight-line portion 130(L) is set so as not to leave the permanent strain in the straight-line portion 130(L).

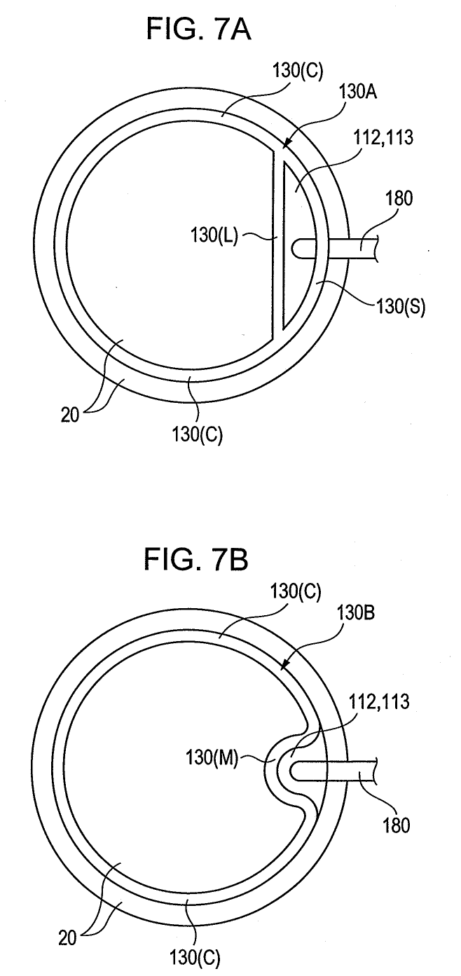

FIGS. 7A and 7B illustrate examples of the shape of the sealing member 130 used in the piezoelectric pump. A sealing member 130A illustrated in FIG. 7A is a modification of the deformed D-shaped sealing member 130 illustrated in FIGS. 3 to 6. In addition to the large arc portion 130(C) and the straight-line portion 130(L), the sealing member 130A includes a supplemental arc portion 130(S) that is connected to the large arc portion 130(C) at the outer side of the straight-line portion 130(L) to form a circle together with the large arc portion 130(C). The sealing member 130A is formed into a deformed circular-shape. In the present embodiment, the supplemental arc portion 130(S) and the feeding terminal 180 intersect with each other. However, the supplemental arc portion 130(S) does not have the function of the sealing member. Therefore, the intersection does not affect the durability of the sealing member 130A. With the feeding terminal 180 pressed by the sealing member 130A, the feeding terminal 180 and the piezoelectric members 112 can be securely adhered with each other.

A sealing member 130B illustrated in FIG. 7B is formed into a deformed horseshoe-shape, and connects the opposite ends of the large arc portion 130(C) with a small arc portion 130(M) in place of the straight-line portion 130(L) of the deformed D-shaped sealing member 130 illustrated in FIGS. 3 to 6. The feeding terminal 180 is connected to the piezoelectric members 112 of the piezoelectric vibrator 20 in a space inside the small arc portion 130(M).

The planar shape of each of the piezoelectric vibrator and the variable volume chambers and the position of the feeding terminal for the piezoelectric members are provided on the surfaces of the piezoelectric vibrator such that the sealing members that form the variable volume chambers together with the piezoelectric vibrator do not intersect with the feeding terminal in a single plane. The shape structures of the piezoelectric vibrator 20 and the feeding terminal 180 illustrated in the drawings are examples. The shape structure is not limited, rather there is design freedom for the shape structures. The configuration of the umbrellas 17A and 17B is not particularly limited. In addition to the unimorph type, the piezoelectric vibrator 20 may be a type in which the piezoelectric members 112 are layered to decrease a drive voltage, for example. The present invention can naturally use these types of piezoelectric vibrators (i.e., the piezoelectric members).

What is claimed is:

1. A piezoelectric pump comprising:
recesses formed in a housing;
a piezoelectric vibrator superimposed between the recesses; and
sealing members provided along the recesses and in contact with the piezoelectric vibrator to form variable volume chambers,
each of the variable volume chambers is smaller in a planar shape than a piezoelectric member provided on a surface of the piezoelectric vibrator, and
a wiring is provided to the piezoelectric member at the outer side of the planar shape of the variable volume chamber.

2. The piezoelectric pump according to claim 1,
wherein the planar shape of the piezoelectric member provided on the surface of the piezoelectric vibrator is circular, and
wherein the planar shape of the variable volume chamber is a noncircular planar shape in which a part of a circle is made noncircular.

3. The piezoelectric pump according to claim 2,
wherein each of the sealing members is formed into a D-shape that includes a large arc portion that is a part of a circle larger than a semicircle thereof, and a straight-line portion that is a straight line connecting opposite ends of the large arc portion.

4. The piezoelectric pump according to claim 3,
wherein the sealing member is formed into a circular-shape that includes a supplemental arc portion that is connected to the large arc portion at the outer side of the straight-line portion to form a circle together with the large arc portion.

5. The piezoelectric pump according to claim 2,
wherein each of the sealing members is formed into an horseshoe-shape that includes a large arc portion that is a part of a circle larger than a semicircle thereof, and an arc portion that connects opposite ends of the large arc portion.

6. The piezoelectric pump according to claim 1,
wherein the piezoelectric vibrator is a bimorph-type piezoelectric device that includes a shim located at the center thereof and the piezoelectric member provided on each of the front surface and the rear surface of the shim.

7. A piezoelectric pump comprising:
a piezoelectric vibrator that includes a piezoelectric member on at least the front surface thereof;
recesses of a housing that form variable volume chambers between the recesses and the piezoelectric vibrator;
sealing members provided along the recesses and in contact with the piezoelectric vibrator to form the variable volume chambers; and
a feeding terminal for the piezoelectric member provided on the at least one of the front surface and the rear surface of the piezoelectric vibrator,
wherein the planar shape of each of the piezoelectric vibrator and the variable volume chambers and the position of the feeding terminal are set such that the sealing members and the feeding terminal do not intersect with each other in a single plane.

8. A piezoelectric pump comprising:
a piezoelectric vibrator that includes a piezoelectric member on at least the rear surface thereof;
recesses of a housing for forming variable volume chambers between the recesses and the piezoelectric vibrator;
sealing members provided along the recesses and in contact with the piezoelectric vibrator to form the variable volume chambers; and
a feeding terminal for the piezoelectric member provided on the at least one of the front surface and the rear surface of the piezoelectric vibrator,
wherein the planar shape of each of the piezoelectric vibrator and the variable volume chambers and the position of the feeding terminal are set such that the sealing members and the feeding terminal do not intersect with each other in a single plane.
